(19) United States
(12) Patent Application Publication
(10) Pub. No.: US 2026/0101755 A1
(43) Pub. Date: Apr. 9, 2026

(54) SEMICONDUCTOR PACKAGE AND METHOD OF FABRICATING THE SAME

(71) Applicant: SAMSUNG ELECTRONICS CO., LTD., Suwon-si (KR)

(72) Inventors: Haseob SEONG, Suwon-si (KR); DAWOON JUNG, Suwon-si (KR)

(73) Assignee: SAMSUNG ELECTRONICS CO., LTD., Suwon-si (KR)

(21) Appl. No.: 19/209,355

(22) Filed: May 15, 2025

(30) Foreign Application Priority Data
Oct. 7, 2024 (KR) 10-2024-0136092

(51) Int. Cl. H01L 23/00; H01L 23/31; H01L 23/34; H01L 25/18

(52) U.S. Cl. CPC H10W 42/121; H10W 40/00; H10W 74/121; H10W 90/00; H10W 72/07353; H10W 72/334; H10W 90/297; H10W 90/732; H10W 90/792

(57) ABSTRACT

A semiconductor package may include: a first semiconductor chip includes a center region and a peripheral region; second semiconductor chips stacked on a top surface of the first semiconductor chip, on the center region; a third semiconductor chip stacked on an uppermost second semiconductor chip from among the second semiconductor chips; an adhesive layer between the uppermost second semiconductor chip and the third semiconductor chip; and a protection layer on the top surface of the first semiconductor chip, wherein the adhesive layer includes an extension portion that protrudes on a side surface of the uppermost second semiconductor chip, and wherein the protection layer includes: a first portion on the peripheral region, on the top surface of the first semiconductor chip; and a second portion extending from the first portion to side surfaces of at least two of the second semiconductor chips.

### CROSS-REFERENCE TO RELATED APPLICATIONS

This U.S. non-provisional patent application claims priority under 35 U.S.C. § 119 to Korean Patent Application No. 10-2024-0136092, filed on Oct. 7, 2024, in the Korean Intellectual Property Office, the disclosure of which is hereby incorporated by reference in its entirety.

### BACKGROUND

### 1. Field

Embodiments of the present disclosure relate to a semiconductor package and a method of fabricating the same.

### 2. Brief Description of Background Art

With the recent advance in the electronics industry, the demand for high-performance, high-speed, and compact electronic components are increasing. To meet this demand, packaging technologies of mounting a plurality of semiconductor chips in a single package are being developed.

Recently, the demand for portable electronic devices has been rapidly increasing in the market, and thus, there is a need to reduce sizes and weights of electronic components constituting the portable electronic devices. For this, there is a need to develop packaging technologies of reducing a size and a weight of each component and of integrating a plurality of individual components in a single package.

In the case where the number of semiconductor chips in a semiconductor package increases, there are difficulties in placing many semiconductor chips in a printed circuit board. In order to alleviate these difficulties, a semiconductor package including an interposer, which is used to connect the semiconductor chips to each other, is being developed.

### SUMMARY

According to an embodiments of the present disclosure, a semiconductor package with an improved mechanical property and a method of fabricating the same are provided.

According to an embodiments of the present disclosure, a semiconductor package with improved stability and a method of fabricating the same are provided.

According to embodiments of the present disclosure, a semiconductor package may be provided and include: a first semiconductor chip includes a center region and a peripheral region; second semiconductor chips stacked on a top surface of the first semiconductor chip, on the center region; a third semiconductor chip stacked on an uppermost second semiconductor chip from among the second semiconductor chips; an adhesive layer between the uppermost second semiconductor chip and the third semiconductor chip; and a protection layer on the top surface of the first semiconductor chip, wherein the adhesive layer includes an extension portion that protrudes on a side surface of the uppermost second semiconductor chip, and wherein the protection layer includes: a first portion on the peripheral region, on the top surface of the first semiconductor chip; and a second portion extending from the first portion to side surfaces of at least two of the second semiconductor chips.

According to embodiments of the present disclosure, a semiconductor package may be provided and include: a first semiconductor chip including a center region and a peripheral region; second semiconductor chips stacked on a top surface of the first semiconductor chip, on the center region,; a third semiconductor chip on an uppermost second semiconductor chip from among the second semiconductor chips; an adhesive layer between the uppermost second semiconductor chip and the third semiconductor chip; a protection layer on the top surface of the first semiconductor chip, on the peripheral region; and a mold layer on the top surface of the first semiconductor chip and surrounding the second semiconductor chips and the third semiconductor chip, wherein the adhesive layer includes an extension portion that extends along side surfaces of the second semiconductor chips from a bottom surface of the third semiconductor chip, wherein the protection layer includes: a first portion on the top surface of the first semiconductor chip, on the peripheral region; and a second portion extending from the first portion to the side surfaces of at least two of the second semiconductor chips, and wherein a width of the protection layer decreases as a distance from a top surface of the second portion and a bottom surface of the second portion increases.

### BRIEF DESCRIPTION OF DRAWINGS

FIGS. 1 and 2 are sectional views illustrating a semiconductor package according to an embodiment of the present disclosure.

FIG. 3 is a sectional view, which is taken along a line A-A′ of FIG. 4, to illustrate a semiconductor package according to an embodiment of the present disclosure.

FIG. 4 is a plan view illustrating a semiconductor package according to an embodiment of the present disclosure.

FIG. 5 is a plan view illustrating a semiconductor package according to an embodiment of the present disclosure.

FIG. 6 is a sectional view, which is taken along a line B-B′ of FIG. 5, to illustrate a semiconductor package according to an embodiment of the present disclosure.

FIGS. 7 to 9 are sectional views illustrating a method of fabricating a semiconductor package according to an embodiment of the present disclosure.

### DETAILED DESCRIPTION

Non-limiting example embodiments of the present disclosures will now be described more fully with reference to the accompanying drawings, in which example embodiments are shown.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

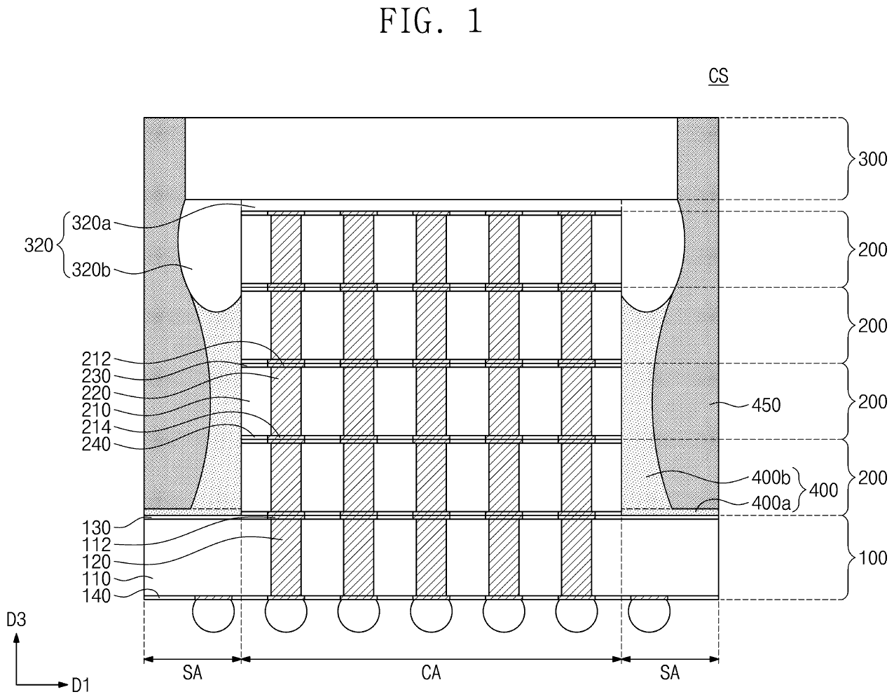

FIG. 1 is a sectional view illustrating a semiconductor package according to an embodiment of the present disclosure. Referring to FIG. 1, a first semiconductor chip 100 may be provided. In the present specification, a first direction D1 may be parallel to a top surface of the first semiconductor chip 100. A second direction D2 may be parallel to the top surface of the first semiconductor chip 100 and may be perpendicular to the first direction D1. A third direction D3 may be perpendicular to the top surface of the first semiconductor chip 100 and may be perpendicular to the first direction D1 and the second direction D2.

The first semiconductor chip 100 may be provided in a face-up manner. The top surface of the first semiconductor chip 100 may be an active surface. In the present specification, a front surface may be defined as an active surface of a semiconductor chip, on which an integrated device or interconnection lines are formed, and a rear surface may be a surface that is opposite to the front surface. The first semiconductor chip 100 may include a first semiconductor substrate 110. The first semiconductor substrate 110 may include a semiconductor material. In an embodiment, the first semiconductor substrate 110 may be formed of or include silicon (Si). According to some embodiments, an integrated device or integrated circuits may be provided on a top surface of the first semiconductor substrate 110. The integrated device or the integrated circuits may include a logic circuit or memory circuit. That is, the first semiconductor chip 100 may be a logic chip or a memory chip.

The first semiconductor substrate 110 may include first penetration vias 120 penetrating the first semiconductor substrate 110. The first penetration vias 120 may be provided to penetrate the first semiconductor substrate 110 in the third direction D3. Ends of the first penetration vias 120 may be coplanar with the top surface of the first semiconductor substrate 110. The first penetration vias 120 may be coupled to the integrated device or the integrated circuits. Opposite ends of the first penetration vias 120 may be exposed to a region below a bottom surface of the first semiconductor substrate 110.

First chip upper pads 112 may be provided on the top surface of the first semiconductor substrate 110. The first chip upper pads 112 may be coupled to the first penetration vias 120. Each of the first chip upper pads 112 may be in contact with a top surface of a corresponding one of the first penetration vias 120. The first chip upper pads 112 and the first penetration vias 120 may include a conductive material. For example, the first chip upper pads 112 and the first penetration vias 120 may be formed of or include copper (Cu). A first insulating layer 130 may be provided on the top surface of the first semiconductor substrate 110. The first insulating layer 130 may cover the top surface of the first semiconductor substrate 110. The first insulating layer 130 may be provided on the first semiconductor substrate 110 to surround (e.g., enclose) the first chip upper pads 112. The first chip upper pads 112 may be exposed to a region on a top surface of the first insulating layer 130. The first insulating layer 130 may be formed of or include silicon oxide (SiOx) or silicon nitride (SiNx).

The first semiconductor chip 100 may further include first chip lower pads provided on the bottom surface of the first semiconductor substrate 110. The first chip lower pads may be coplanar with the bottom surface of the first semiconductor substrate 110 and may be exposed to a region below the bottom surface of the first semiconductor substrate 110. However, embodiments of the present disclosure are not limited to this example, and in an embodiment, the first chip lower pads may protrude to a region below the bottom surface of the first semiconductor substrate 110. The first chip lower pads may be electrically connected to the integrated device or the integrated circuits through the first penetration vias 120. A second insulating layer 140 may be provided to cover the bottom surface of the first semiconductor substrate 110. The second insulating layer 140 may be provided on the bottom surface of the first semiconductor substrate 110 to enclose the first chip lower pads. The first chip lower pads may be exposed to a region below a bottom surface of the second insulating layer 140. The second insulating layer 140 may be formed of or include an insulating material (e.g., silicon oxide (SiOx) or silicon nitride (SiNx)).

Outer connection terminals may be provided on bottom surfaces of the first chip lower pads. The outer connection terminals may include solder balls or solder bumps. Ends of the outer connection terminals may be in contact with the first chip lower pads. The outer connection terminals may be electrically connected to the integrated device or the integrated circuits in the first semiconductor chip 100.

The first semiconductor chip 100 may include a center region CA and a peripheral region SA surrounding (e.g., enclosing) the center region CA. In the present specification, the center region CA of the first semiconductor chip 100 may mean a region of the first semiconductor chip 100, on which second semiconductor chips 200 are provided. In addition, despite of its name, the center region CA is not restricted to the region located on the center of the first semiconductor chip 100, and a region of the first semiconductor chip 100 located below the second semiconductor chips 200 may be defined as the center region CA. In the present specification, the peripheral region SA may be defined as a region of the first semiconductor chip 100 surrounding (e.g., enclosing) the center region CA. Similarly, despite of its name, the peripheral region SA is not restricted to the region located on an edge of the first semiconductor chip 100, and a remaining region, excluding the center region CA, may be defined as the peripheral region SA. In an embodiment, the center region CA and the peripheral region SA may be in contact with each other.

FIG. 1 illustrates the first semiconductor chip 100 provided in a face-up manner, but embodiments of the present disclosure are not limited to this example. The first semiconductor chip 100 may be disposed in a face-down manner. For example, a bottom surface of the first semiconductor chip 100 may be an active surface of the first semiconductor chip 100.

A second semiconductor chip 200 may be provided on a center portion of the top surface of the first semiconductor chip 100. The second semiconductor chip 200 may be provided on the first semiconductor chip 100 in a face-down manner. The second semiconductor chip 200 may have a front surface and a rear surface. The front surface of the second semiconductor chip 200 may face the top surface of the first semiconductor chip 100. A bottom surface of the second semiconductor chip 200 may be an active surface. The second semiconductor chip 200 may include a second semiconductor substrate 210. The second semiconductor substrate 210 may be a semiconductor substrate. As an example, the second semiconductor substrate 210 may be formed of or include silicon (Si). In detail, an integrated device or integrated circuits may be provided on a bottom surface of the second semiconductor substrate 210. The integrated device or the integrated circuits may include a memory circuit. For example, the second semiconductor chip 200 may be a memory chip (e.g., a dynamic random-access memory (DRAM) chip, a static random-access memory (SRAM) chip, a magnetoresistive random-access memory (MRAM) chip, or a FLASH memory chip). However, embodiments of the present disclosure are not limited to this example, and in an embodiment, the second semiconductor chip 200 may be provided in a face-up manner. In an embodiment, a top surface of the second semiconductor chip 200 may be an active surface.

The second semiconductor chip 200 may include second penetration vias 220. The second penetration vias 220 may be provided to penetrate the second semiconductor substrate 210 in the third direction D3. The second penetration vias 220 may be electrically connected to the integrated device or the integrated circuits.

Second chip upper pads 212 may be provided on a top surface of the second semiconductor substrate 210. The second chip upper pads 212 may protrude to a region on the top surface of the second semiconductor substrate 210. The second chip upper pads 212 may be coupled to the second penetration vias 220. Each of the second chip upper pads 212 may be in contact with a top surface of a corresponding one of the second penetration vias 220. The second chip upper pads 212 and the second penetration vias 220 may include a conductive material. For example, the second chip upper pads 212 and the second penetration vias 220 may be formed of or include copper (Cu). A third insulating layer 230 may be provided on the top surface of the second semiconductor substrate 210. The third insulating layer 230 may cover the top surface of the second semiconductor substrate 210. The third insulating layer 230 on the second semiconductor substrate 210 may be provided to surround (e.g., enclose) the second chip upper pads 212. The second chip upper pads 212 may be exposed to a region on a top surface of the third insulating layer 230. The third insulating layer 230 may be formed of or include silicon oxide (SiOx) or silicon nitride (SiNx).

The second semiconductor chip 200 may further include second chip lower pads 214 provided on the bottom surface of the second semiconductor substrate 210. The second chip lower pads 214 may protrude to a region below the bottom surface of the second semiconductor substrate 210. The second chip lower pads 214 may be electrically connected to the integrated device or the integrated circuits through the second penetration vias 220. A fourth insulating layer 240 may be provided to cover the bottom surface of the second semiconductor substrate 210. The fourth insulating layer 240 may cover the bottom surface of the second semiconductor substrate 210. The fourth insulating layer 240 on the bottom surface of the second semiconductor substrate 210 may surround (e.g., enclose) the second chip lower pads 214. The second chip lower pads 214 may be exposed to a region below a bottom surface of the fourth insulating layer 240. The fourth insulating layer 240 may be formed of or include silicon oxide (SiOx) or silicon nitride (SiNx).

A width of the second semiconductor chip 200 in the first direction D1 may be smaller than a width of the first semiconductor chip 100 in the first direction D1. A height of the second semiconductor chip 200 in the third direction D3 may range from 25 μm to 60 μm, but embodiments of the present disclosure are not limited to this example.

In an embodiment, a plurality of second semiconductor chips 200 may be provided. On the center region CA, the second semiconductor chips 200 may be stacked on the top surface of the first semiconductor chip 100. In an embodiment, 4 to 32 second semiconductor chips 200 may be stacked, but embodiments of the present disclosure are not limited to this example. The second semiconductor chips 200 may be directly connected to each other. One of the second semiconductor chips 200 may be coupled to the second penetration vias 220 of another one of the second semiconductor chips 200 disposed therebelow. The second chip lower pads 214 of one of the second semiconductor chips 200 may be vertically aligned to the second chip upper pads 212 of another one of the second semiconductor chips 200. Side surfaces of the second semiconductor chips 200 may be aligned to each other in the third direction D3. For example, the side surfaces of the second semiconductor chips 200 may be coplanar with each other.

The fourth insulating layer 240 of one of the second semiconductor chips 200 may be bonded to the third insulating layer 230 of another one of the second semiconductor chips 200. Here, the third insulating layer 230 and the fourth insulating layer 240 may form an oxide, nitride, or oxynitride hybrid bonding structure. In the present specification, the hybrid bonding structure may mean a bonding structure that is formed by two materials, which are of the same kind and are fused at an interface therebetween. For example, the third insulating layer 230 and the fourth insulating layer 240, which are bonded to each other, may have a continuous structure, and in this case, there may be no observable interface between the third insulating layer 230 and the fourth insulating layer 240. The third insulating layer 230 and the fourth insulating layer 240 may be formed of the same material to form a single object. In other words, the third insulating layer 230 and the fourth insulating layer 240 may be bonded to each other to form a single object. However, embodiments of the present disclosure are not limited to this example. The third insulating layer 230 and the fourth insulating layer 240 may be formed of different materials, and the third insulating layer 230 and the fourth insulating layer 240 may not have a continuous structure.

At an interface of two adjacent ones of the second semiconductor chip 200, the second chip lower pads 214 of one of the second semiconductor chips 200 may be directly bonded to the second chip upper pads 212 of another one of the second semiconductor chips 200. For example, the second chip lower pads 214 and the second chip upper pads 212 may form an inter-metal hybrid bonding structure. The second chip lower pads 214 and the second chip upper pads 212, which are bonded to each other, may have a continuous structure, and in this case, there may be no observable interface between the second chip lower pads 214 and the second chip upper pads 212. For example, the second chip lower pads 214 and the second chip upper pads 212 may be formed of the same material and may be provided as a single object. For example, the second chip lower pads 214 and the second chip upper pads 212 may be bonded to each other to form a single object.

The lowermost one of the second semiconductor chips 200 may be directly connected to the first semiconductor chip 100. The lowermost one of the second semiconductor chips 200 may be coupled to the first penetration vias 120 of the first semiconductor chip 100. The second chip lower pads 214 of the lowermost one of the second semiconductor chips 200 may be vertically aligned to the first chip upper pads 112 of the first semiconductor chip 100.

The fourth insulating layer 240 of the lowermost one of the second semiconductor chips 200 may be bonded to the first insulating layer 130 of the first semiconductor chip 100. Here, the first insulating layer 130 and the fourth insulating layer 240 may form an oxide, nitride, or oxynitride hybrid bonding structure. The first insulating layer 130 and the fourth insulating layer 240, which are bonded to each other, may have a continuous structure, and in this case, there may be no observable interface between the first insulating layer 130 and the fourth insulating layer 240. The first insulating layer 130 and the fourth insulating layer 240 may be formed of the same material and may be provided as a single object. That is, the first insulating layer 130 and the fourth insulating layer 240 may be bonded to each other to form a single object. However, embodiments of the present disclosure are not limited to this example. The first insulating layer 130 and the fourth insulating layer 240 may be formed of different materials, and the first insulating layer 130 and the fourth insulating layer 240 may not have a continuous structure.

At an interface between the lowermost one of the second semiconductor chips 200 and the first semiconductor chip 100, the second chip lower pads 214 of the lowermost one of the second semiconductor chips 200 may be directly bonded to the first chip upper pads 112 of the first semiconductor chip 100. For example, the second chip lower pads 214 and the first chip upper pads 112 may form an inter-metal hybrid bonding structure. The second chip lower pads 214 and the first chip upper pads 112, which are bonded to each other, may have a continuous structure, and in this case, there may be no observable interface between the second chip lower pads 214 and the first chip upper pads 112. For example, the second chip lower pads 214 and the first chip upper pads 112 may be formed of the same material and may be provided as a single object. For example, the second chip lower pads 214 and the first chip upper pads 112 may be bonded to each other to form a single object.

A thickness of the uppermost one of the second semiconductor chips 200 may be equal to or larger than a thickness of another of the second semiconductor chips 200 therebelow. However, embodiments of the present disclosure are not limited to this example. In an embodiment, the uppermost one of the second semiconductor chips 200 may not include the second penetration vias 220 and the second chip upper pads 212.

A third semiconductor chip 300 may be provided on a top surface of the uppermost one of the second semiconductor chips 200. The third semiconductor chip 300 may include a semiconductor material. In an embodiment, the third semiconductor chip 300 may be formed of or include silicon (Si). A width of the third semiconductor chip 300 in the first direction D1 may be equal to or larger than the width of each of the second semiconductor chips 200 in the first direction D1.

An adhesive layer 320 may be provided between the third semiconductor chip 300 and the uppermost one of the second semiconductor chips 200. The adhesive layer 320 may be provided to fill a space between the third semiconductor chip 300 and the uppermost one of the second semiconductor chips 200. The adhesive layer 320 may include an adhesion portion 320a, which is interposed between the third semiconductor chip 300 and the uppermost one of the second semiconductor chips 200, and an extension portion 320b, which protrudes from the side surface of the uppermost one of the second semiconductor chips 200 in an outward direction. The extension portion 320b may be extended from a bottom surface of the third semiconductor chip 300 to the side surfaces of the second semiconductor chips 200 to cover at least a portion of the side surfaces of the second semiconductor chips 200. The extension portion 320b may cover the side surface of at least one second semiconductor chip 200.

In the present specification, for convenience in description, the adhesive layer 320 will be described to include two different portions (i.e., the adhesion portion 320a and the extension portion 320b), but this does not mean that the adhesion portion 320a and the extension portion 320b are individual elements. The adhesion portion 320a and the extension portion 320b may be two different portions of the adhesive layer 320, which are spatially distinct from each other. That is, the adhesion portion 320a and the extension portion 320b may be formed of the same material and may have a continuous structure. There may be no observable interface between the adhesion portion 320a and the extension portion 320b. The adhesion portion 320a and the extension portion 320b may be provided as a single element. The adhesive layer 320 may include a non-conductive film (NCF). The third semiconductor chip 300 may be attached to the uppermost one of the second semiconductor chips 200 using the adhesive layer 320.

On the peripheral region SA, a protection layer 400 may be provided on the top surface of the first semiconductor chip 100. The protection layer 400 may include a first portion 400a and a second portion 400b. On the peripheral region SA, the first portion 400a may cover the top surface of the first semiconductor chip 100. On the peripheral region SA, the second portion 400b may extend from the top surface of the first semiconductor chip 100 to the side surfaces of the second semiconductor chips 200.

The first portion 400a may be provided on the peripheral region SA to cover the top surface of the first semiconductor chip 100. The first portion 400a may cover a region of the top surface of the first semiconductor chip 100, except a region in which the second semiconductor chips 200 are provided. A side surface of the first portion 400a may be aligned to (e.g., coplanar with) a side surface of the first semiconductor chip 100 or may be placed more inwards than the side surface of the first semiconductor chip 100. In other words, the first portion 400a may not protrude past the side surface of the first semiconductor chip 100. The height of the first portion 400a in the third direction D3 may range from 1 μm to 10 μm.

The second portion 400b may extend from a top surface of the first portion 400a, which may be on the top surface of the first semiconductor chip 100. The second portion 400b may be provided to enclose a remaining region of the side surfaces of the second semiconductor chips 200. In the present specification, the remaining region of the side surfaces of the second semiconductor chips 200 may mean at least a portion of the side surfaces of the second semiconductor chips 200, which is not surrounded (e.g., enclosed) by the extension portion 320b of the adhesive layer 320. That is, the second portion 400b and the extension portion 320b of the adhesive layer 320 may be provided to fully surround (e.g., enclose) the side surfaces of the second semiconductor chips 200. A top end of the second portion 400b may be in contact with a bottom end of the extension portion 320b of the adhesive layer 320. Due to the second portion 400b and the extension portion 320b of the adhesive layer 320, the side surfaces of the second semiconductor chips 200 may not be exposed to the outside.

A width of the second portion 400b in the first direction D1 may be smaller than a width of the first portion 400a in the first direction D1. Here, the width of the first portion 400a may mean a width from a side surface of the second semiconductor chips 200 to an outer side surface of the first portion 400a. The width of the second portion 400b may mean a width from a side surface of the second semiconductor chip 200 to an outer side surface of the second portion 400b. The width of the second portion 400b in the first direction D1 may not be constant, as a distance in the third direction D3 varies. As an example, the width of the second portion 400b may decrease as a distance from the top and bottom surfaces of the second portion 400b increases. That is, the outer side surface of the second portion 400b may be a concave surface that has center portion that is recessed toward the second semiconductor chips 200.

The protection layer 400 may include a thermosetting material. In detail, the protection layer 400 may be formed of or include an insulating polymer material. As an example, the protection layer 400 may be formed of or include an epoxy-based polymer. In the present specification, the protection layer 400 may be defined as separate elements (e.g., the first portion 400a and the second portion 400b), for convenience in description, but each of the first portion 400a and the second portion 400b may not be a separate element. The first portion 400a and the second portion 400b may be two portions of the protection layer 400, which are spatially distinct from each other. In other words, the first portion 400a and the second portion 400b may be formed of the same material and may have a continuous structure. There may be no observable interface between the first portion 400a and the second portion 400b. The first portion 400a and the second portion 400b may be provided as a single element.

In addition, FIG. 1 illustrates an example in which the width of the first portion 400a of the protection layer 400 is constant, but embodiments of the present disclosure are not limited to this example. In an embodiment, a width of the protection layer 400 in the first direction D1 may not be constant. The width of the protection layer 400 may decrease, as a distance from the top and bottom surfaces of the protection layer 400 increases. In other words, the protection layer 400 may have an inner side surface, which is in contact with the side surfaces of the second semiconductor chips 200, and an outer side surface, which is opposite to the inner side surface. Furthermore, the protection layer 400 may have a first inclined surface, which connects the top surface and the outer side surface of the protection layer 400, and a second inclined surface, which connects the bottom surface and the outer side surface of the protection layer 400. The inner side surface of the protection layer 400 may be perpendicular to the top surface of the first semiconductor chip 100. The first and second inclined surfaces may be inclined relative to the inner side surface in an outward direction from the side surfaces of the second semiconductor chips 200.

A mold layer 450 may be provided on the top surface of the first semiconductor chip 100. On the peripheral region SA, the mold layer 450 may cover a top surface of the first portion 400a of the protection layer 400. The mold layer 450 may surround (e.g., enclose) the second portion 400b of the protection layer 400, the adhesive layer 320, and the third semiconductor chip 300. A top surface of the mold layer 450 may be coplanar with a top surface of the third semiconductor chip 300.

The mold layer 450 may include an insulating polymer material. For example, the mold layer 450 may be formed of or include an epoxy molding compound (EMC). In an embodiment, the mold layer 450 may be formed of or include the same material as the material of the protection layer 400. However, embodiments of the present disclosure are not limited to this example.

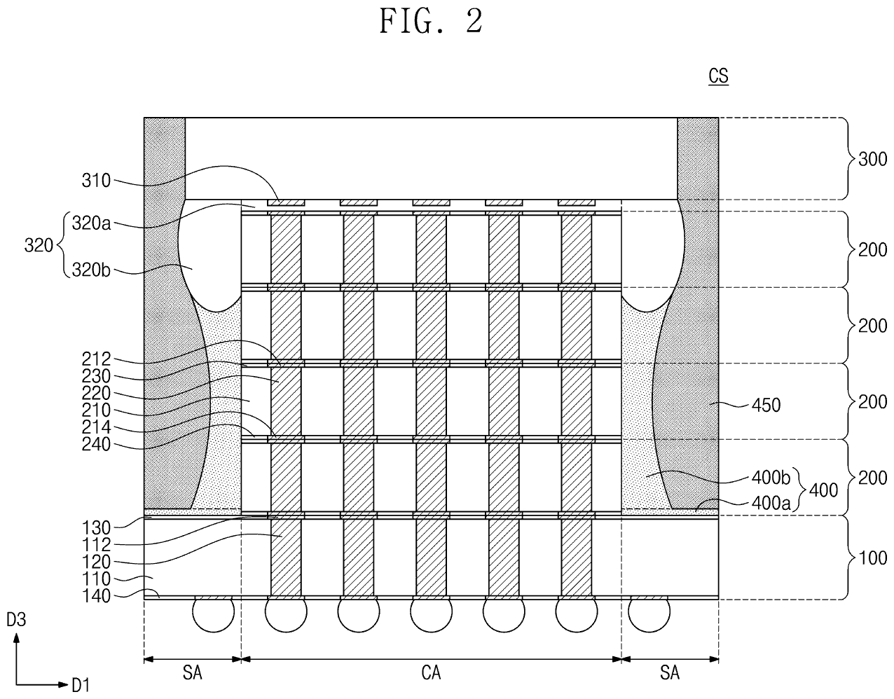

FIG. 2 is a sectional view illustrating a semiconductor package according to an embodiment of the present disclosure. Referring to FIG. 2, the third semiconductor chip 300 may further include heat-dissipation pads 310 provided on the bottom surface of the third semiconductor chip 300. The heat-dissipation pads 310 may be horizontally spaced apart from each other, on the bottom surface of the third semiconductor chip 300. The heat-dissipation pads 310 may include a conductive material. For example, the heat-dissipation pads 310 may be formed of or include copper (Cu). When viewed in a plan view, the heat-dissipation pads 310 may be vertically aligned to (e.g., overlapping with) the second chip upper pads 212, respectively, of a corresponding one of the second semiconductor chips 200. The heat-dissipation pads 310 may be spaced apart from the second chip upper pads 212 of the uppermost one of the second semiconductor chips 200 in the third direction D3. That is, the heat-dissipation pads 310 may not be in contact with the second chip upper pads 212 of the uppermost one of the second semiconductor chips 200. However, embodiments of the present disclosure are not limited to this example, and in an embodiment, the number and arrangement of the heat-dissipation pads 310 may be different from the number and arrangement of the second chip upper pads 212 of the uppermost one of the second semiconductor chips 200.

The adhesive layer 320 may be provided on the bottom surface of the third semiconductor chip 300 to surround (e.g., enclose) the heat-dissipation pads 310. In detail, the adhesion portion 320a of the adhesive layer 320 may be provided on the top surface of the uppermost one of the second semiconductor chips 200 to fill a space between the heat-dissipation pads 310 and the second chip upper pads 212 of the uppermost one of the second semiconductor chips 200.

Since the heat-dissipation pads 310 are provided on the bottom surface of the third semiconductor chip 300, heat, which is generated from the second semiconductor chips 200, may be transmitted to the third semiconductor chip 300 and may be quickly exhausted to the outside. Since the heat-dissipation pads 310 are formed of a conductive material with high thermal conductivity, the heat, which is generated from the second semiconductor chips 200, may be quickly exhausted to a region on the third semiconductor chip 300 through the heat-dissipation pads 310. As a result, it may be possible to realize the semiconductor package with improved heat-dissipation efficiency.

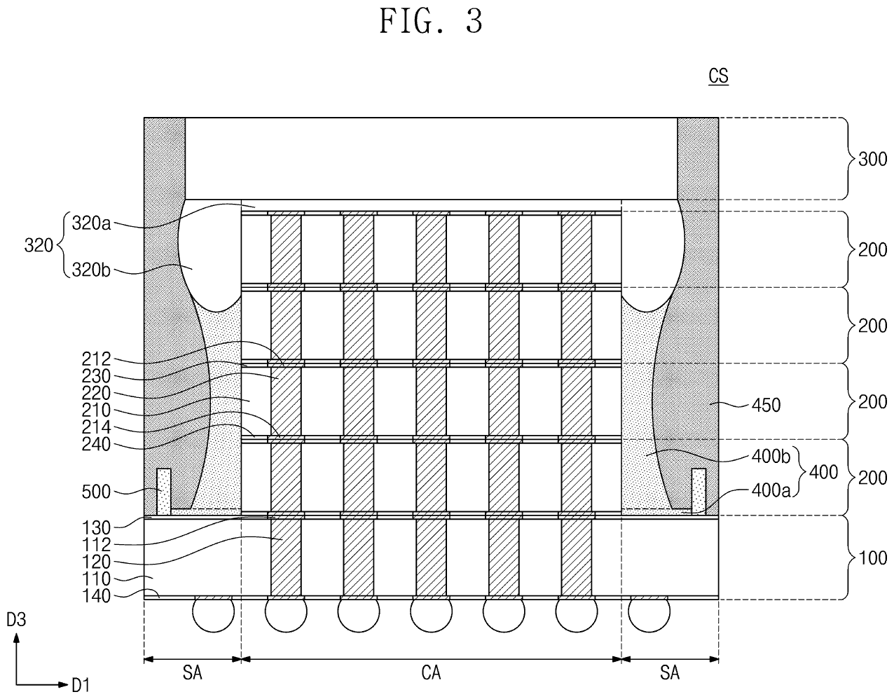

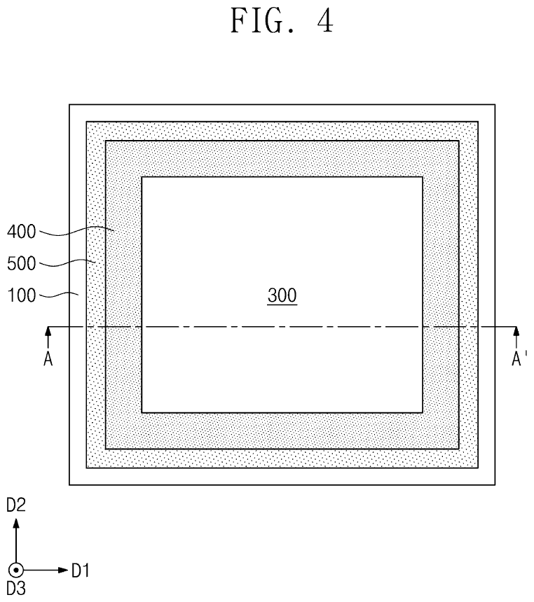

FIG. 3 is a sectional view illustrating a semiconductor package according to an embodiment of the present disclosure. FIG. 4 is a plan view illustrating a semiconductor package according to an embodiment of the present disclosure and illustrating the first semiconductor chip 100, the third semiconductor chip 300, the protection layer 400, and a dam structure 500. For convenience of description, other elements may not be illustrated. FIG. 3 is a sectional view taken along a line A-A′ of FIG. 4. Referring to FIGS. 3 and 4, the dam structure 500 may be provided on the first semiconductor chip 100. On the peripheral region SA, the dam structure 500 may be provided on the top surface of the first semiconductor chip 100. When viewed in a plan view, the dam structure 500 may be provided between the side surfaces of the second semiconductor chips 200 and an outer side surface of the first semiconductor chip 100. The dam structure 500 may protrude upwards on the top surface of the first semiconductor chip 100. When viewed in a plan view, the dam structure 500 may have a closed loop shape. More specifically, the dam structure 500 may have a rectangular ring shape or a closed-loop shape, when viewed in a plan view. When viewed in a plan view, the dam structure 500 may be provided to surround (e.g., enclose) the second semiconductor chips 200 and the third semiconductor chip 300.

The dam structure 500 may include an insulating polymer. As an example, the dam structure 500 may be formed of or include polyimide. However, embodiments of the present disclosure are not limited to this example, and in an embodiment, the material of the dam structure 500 may be variously changed.

The protection layer 400 may be provided on an inner region of the dam structure 500, which is delimited by an inner side surface of the dam structure 500. The inner side surface of the dam structure 500 may be in contact with the side surface of the first portion 400a. When viewed in a plan view, the dam structure 500 may surround (e.g., enclose) the first portion 400a. The first portion 400a may be provided between the second semiconductor chips 200 and the dam structure 500 to cover a portion of the top surface of the first semiconductor chip 100.

A region of the first semiconductor chip 100, on which the protection layer 400 is provided, may be confined by the dam structure 500. That is, the dam structure 500 may define a region in which the protection layer 400 is formed. The side surface of the first portion 400a may not be exposed to a region on the side surface of the first semiconductor chip 100 due to the dam structure 500.

FIGS. 3 and 4 illustrate an example, in which the dam structure 500 is provided to have a ring shape or a closed-loop shape and to surround (e.g., enclose) the first portion 400a in a plan view, but embodiments of the present disclosure are not limited to this example. The arrangement and number of the dam structure 500 may be variously changed. In an embodiment, a plurality of dam structures 500 may be provided. The dam structures 500 may be disposed to be spaced apart from each other along an edge of the first portion 400a. For example, the protection layer 400 may be disposed between the dam structures 500. In detail, one or more dam structures 500 may be disposed near the first portion 400a, and the dam structures 500 may be provided to have inner side surfaces that are in contact with the side surface of the first portion 400a.

In an embodiment, the dam structures 500 may not completely surround the side surface of the first portion 400a. The dam structures 500 may be provided to surround (e.g., enclose) at least one of side surfaces of the first portion 400a or at least one of corners of the first portion 400a, not all of the side surfaces of the first portion 400a. The dam structures 500 may have a non-rectangular closed-loop structure or a partially-open structure (e.g., a squared C-shaped structure or an angular C-shaped structure), when viewed in a plan view.

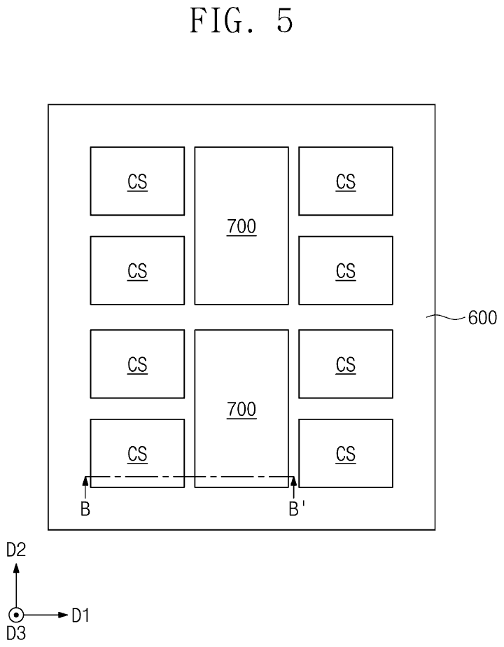

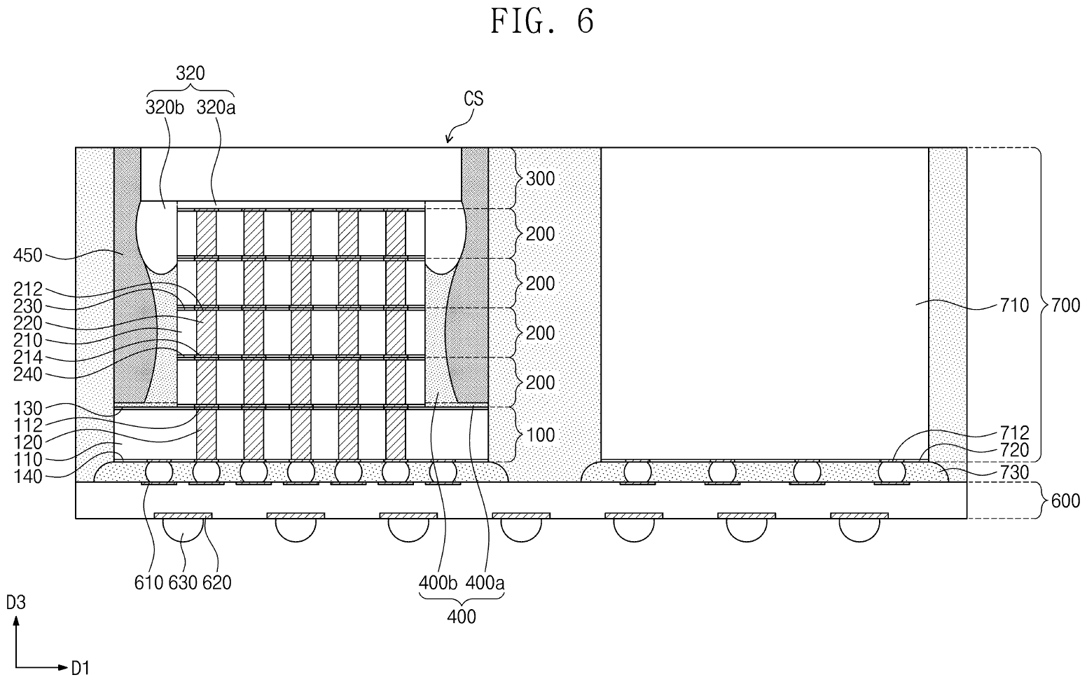

FIG. 5 is a plan view illustrating a semiconductor package according to an embodiment of the present disclosure. FIG. 6 is a sectional view, which is taken along a line B-B′ of FIG. 5, to illustrate a semiconductor package according to an embodiment of the present disclosure. Referring to FIGS. 5 and 6, the semiconductor package may include a substrate 600, chip stacks CS, and a fourth semiconductor chip 700. In an embodiment, a plurality of fourth semiconductor chips 700 may be provided on the substrate 600. The fourth semiconductor chips 700 on the substrate 600 may be spaced apart from each other in the second direction D2. In an embodiment, a plurality of chip stacks CS may be provided on the substrate 600. The chip stacks CS may be separated from each of the fourth semiconductor chips 700 in the first direction D1 and the opposite direction thereof. One or more chip stacks CS may be separated from each of the fourth semiconductor chips 700 in the first direction D1 and the opposite direction thereof. That is, the chip stacks CS may be disposed to form at least two columns extending in the second direction D2. The two columns of the chip stacks CS may be spaced apart from each other in the first direction D1. The fourth semiconductor chips 700 may be provided between the two columns of the chip stacks CS.

The substrate 600 may be a redistribution substrate. For example, the substrate 600 may include one substrate interconnection layer or may include at least two substrate interconnection layers, which are stacked. In the present specification, the substrate interconnection layer may mean an interconnection layer, which includes a patterned structure of a single insulating layer and a patterned structure of a single conductive layer. Each of the substrate interconnection layers may include an insulating pattern and a conductive pattern in the insulating pattern. The conductive pattern of one of the substrate interconnection layers may be electrically connected to the conductive pattern of a neighboring one of the substrate interconnection layers.

The substrate 600 may include upper substrate pads 610. The upper substrate pads 610 may be upper portions of the conductive pattern of the uppermost one of the substrate interconnection layers or additional pads electrically connected to the conductive pattern in the substrate interconnection layer. The upper substrate pads 610 may be disposed at (e.g., in or on) the top surface of the substrate 600. The upper substrate pads 610 may be coplanar with the top surface of the substrate 600 and may be exposed to a region on the substrate 600. However, embodiments of the present disclosure are not limited to this example, and in an embodiment, the upper substrate pads 610 may protrude above the top surface of the substrate 600.

FIGS. 5 and 6 illustrate an example, in which the substrate 600 is a redistribution substrate, but embodiments of the present disclosure are not limited to this example. In an embodiment, the substrate 600 may be a printed circuit board (PCB). Here, the substrate 600 may include an internal interconnection pattern provided therein. For example, the substrate 600 may have a structure, in which insulating patterns and internal interconnection patterns are alternately stacked. Here, the upper substrate pads 610 may be additional pads, which are electrically connected to the internal interconnection pattern, or portions of the internal interconnection pattern exposed to a region on the top surface of the substrate 600. For brevity's sake, example embodiments of the present disclosure will be described with reference to FIGS. 5 and 6.

Lower substrate pads 620 and substrate connection terminals 630 may be provided at (e.g., in or on) a bottom surface of the substrate 600. The lower substrate pads 620 may be additional pads, which are disposed at (e.g., in or on) the bottom surface of the substrate 600 and are connected to the conductive pattern of the substrate 600, or portions of the conductive pattern, which are exposed to a region below the bottom surface of the substrate 600. However, embodiments of the present disclosure are not limited to this example, and in an embodiment, the lower substrate pads 620 may protrude below the bottom surface of the substrate 600. Each of the substrate connection terminals 630 may be disposed on a bottom surface of a corresponding one of the lower substrate pads 620. The substrate connection terminals 630 may include solder balls or solder bumps.

The fourth semiconductor chips 700 and the chip stacks CS may be disposed on the top surface of the substrate 600. Hereinafter, for convenience in description, the structure of the fourth semiconductor chips 700 will be described in more detail with reference to one of the fourth semiconductor chips 700, and the structure of the chip stacks CS will be described in more detail with reference to one of the chip stacks CS.

The fourth semiconductor chip 700 may be provided on the substrate 600 in a face-down manner. The fourth semiconductor chip 700 may have a front surface and a rear surface. The front surface of the fourth semiconductor chip 700 may face the top surface of the substrate 600. A bottom surface of the fourth semiconductor chip 700 may be an active surface. The fourth semiconductor chip 700 may include a fourth semiconductor substrate 710. The fourth semiconductor substrate 710 may include a semiconductor material. As an example, the fourth semiconductor substrate 710 may be formed of or include silicon (Si). According to some embodiments, an integrated device or integrated circuits may be provided on the bottom surface of the fourth semiconductor chip 700. The integrated device or the integrated circuits may include a logic circuit. That is, the fourth semiconductor chip 700 may be a logic chip.

Fourth chip pads 712 may be provided on a bottom surface of the fourth semiconductor substrate 710. The fourth chip pads 712 may be coplanar with the bottom surface of the fourth semiconductor substrate 710 and may protrude to a region below the bottom surface of the fourth semiconductor chip 700. However, embodiments of the present disclosure are not limited to this example, and in an embodiment, the fourth chip pads 712 may be coplanar with the bottom surface of the fourth semiconductor substrate 710 and may be exposed to a region below the bottom surface of the fourth semiconductor substrate 710. The fourth chip pads 712 may be electrically connected to the integrated device or the integrated circuits. The fourth chip pads 712 may include a conductive material. For example, the fourth chip pads 712 may be formed of or include copper (Cu). A fifth insulating layer 720 may be provided on the bottom surface of the fourth semiconductor substrate 710. The fifth insulating layer 720 may cover the bottom surface of the fourth semiconductor substrate 710. The fifth insulating layer 720 on the fourth semiconductor substrate 710 may surround (e.g., enclose) the fourth chip pads 712. The fourth chip pads 712 may be exposed to a region on a bottom surface of the fifth insulating layer 720. The fifth insulating layer 720 may be formed of or include silicon oxide (SiOx) or silicon nitride (SiNx).

Chip connection terminals (e.g., solder balls or solder bumps) may be provided on bottom surfaces of the fourth chip pads 712. Ends of the chip connection terminals may be in contact with the fourth chip pads 712. An opposite end of each of the chip connection terminals may be in contact with a corresponding one of the upper substrate pads 610. The fourth semiconductor chip 700 may be mounted on the substrate 600 by the chip connection terminals.

A first under-fill layer 730 may be provided between the bottom surface of the fourth semiconductor chip 700 and the top surface of the substrate 600. The first under-fill layer 730 may be provided to fill spaces between the substrate 600 and the fourth semiconductor chip 700 and to surround (e.g., enclose) the chip connection terminals.

The chip stack CS may be configured to have substantially the same or similar features as the chip stack CS described with reference to FIG. 1. The chip stack CS may be mounted on the substrate 600 by the outer connection terminals described with reference to FIG. 1. Ends of the outer connection terminals may be in contact with the bottom surfaces of the first chip lower pads. The outer connection terminals may be electrically connected to the integrated device or the integrated circuits in the first semiconductor chip 100. Opposite ends of the outer connection terminals may be in contact with the upper substrate pads 610 of the substrate 600.

A second under-fill layer may be provided between a bottom surface of the chip stack CS and the top surface of the substrate 600. The second under-fill layer may be provided to fill spaces between the substrate 600 and the chip stack CS and to surround (e.g., enclose) the outer connection terminals.

FIG. 5 illustrates a semiconductor package including the fourth semiconductor chips 700 and the chip stacks CS, but embodiments of the present disclosure are not limited to this example. The fourth semiconductor chips 700 and the chip stack CS may be provided individually on the substrate 600. Here, the fourth semiconductor chips 700 and the chip stack CS may be spaced apart from each other, on the substrate 600. Alternatively, the fourth semiconductor chip 700 and the chip stacks CS may be provided. For example, the chip stacks CS may be spaced apart from each other in the second direction D2 and may be disposed at a side of the fourth semiconductor chip 700. As described above, the number and arrangement of the fourth semiconductor chips 700 and the chip stacks CS may vary.

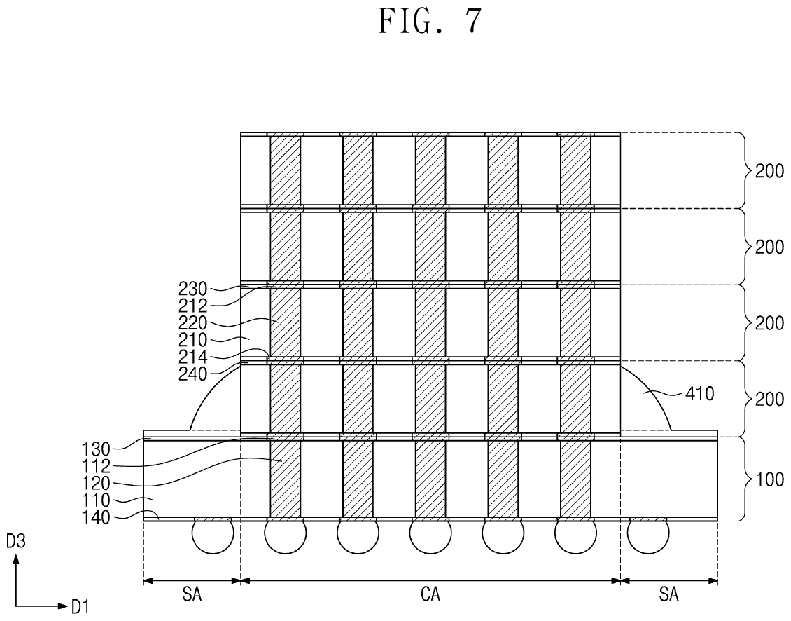

FIGS. 7 to 9 are sectional views illustrating a method of fabricating a semiconductor package according to an embodiment of the present disclosure.

Referring to FIG. 7, the first semiconductor chip 100 may be provided. The second semiconductor chips 200 may be stacked on the center region CA of the first semiconductor chip 100. Here, the first semiconductor chip 100 and the second semiconductors chip 200 may be configured to have substantially the same features as described with reference to FIG. 1. The second semiconductor chips 200 may be provided in such a way that the second chip lower pads 214 face the second chip upper pads 212 of another second semiconductor chip 200 therebelow. The lowermost one of the second semiconductor chips 200 may be provided in such a way that the second chip lower pads 214 face the first chip upper pads 112 of the first semiconductor chip 100. A first thermal treatment process may be performed on the first semiconductor chip 100 and the second semiconductor chips 200. The first thermal treatment process may include applying heat to the first semiconductor chip 100 and the second semiconductor chip 200. In an embodiment, during the first thermal treatment process, the second chip lower pads 214 of the lowermost one of the second semiconductor chips 200 may be bonded to the first chip upper pads 112, and the second chip lower pads 214, which are respectively included in adjacent ones of the second semiconductor chips 200, may be bonded to each other.

The second chip lower pads 214 of the lowermost one of the second semiconductor chips 200 may be naturally bonded to the first chip upper pads 112. In detail, the first chip upper pads 112 and the second chip lower pads 214 may be formed of the same material (e.g., copper (Cu)), and in this case, the first chip upper pads 112 and the second chip lower pads 214 may be bonded to each other by an inter-metal hybrid bonding process (e.g., Cu-Cu hybrid bonding process) that is caused by the surface activation on a first bonding surface between the first chip upper pads 112 and the second chip lower pads 214, which are in contact with each other. The first insulating layer 130 and the fourth insulating layer 240 may be bonded to each other by the first thermal treatment process. For example, the first insulating layer 130 and the fourth insulating layer 240 may be bonded to each other to form a single object.

The second chip lower pads 214 and the second chip upper pads 212, which are respectively included in the vertically adjacent ones of the second semiconductor chips 200, may be naturally bonded to each other. In detail, the second chip upper pads 212 and the second chip lower pads 214 may be formed of the same material (e.g., copper (Cu)), and in this case, the second chip upper pads 212 and the second chip lower pads 214 may be bonded to each other by an inter-metal hybrid bonding process (e.g., Cu-Cu hybrid bonding) that is caused by the surface activation on a second bonding surface between the second chip upper pads 212 and the second chip lower pads 214, which are in contact with each other. The third insulating layer 230 and the fourth insulating layer 240 may be bonded to each other by the first thermal treatment process. For example, the third insulating layer 230 and the fourth insulating layer 240 may be bonded to each other to form a single object.

The peripheral region SA of the first semiconductor chip 100 may be coated with a protection layer precursor 410. The protection layer precursor 410 may be formed on the peripheral region SA to cover the top surface of the first semiconductor chip 100. The protection layer precursor 410 may be in contact with a side surface of the lowermost one of the second semiconductor chips 200. A height of the protection layer precursor 410 in the third direction D3 may vary depending on a distance in the first direction D1. In an embodiment, the height of the protection layer precursor 410 in the third direction D3 may be constant in a region from the side surface of the first semiconductor chip 100 to a position separated therefrom in the first direction D1 by a specific distance. The height of the protection layer precursor 410 in the third direction D3 may increase as it moves from the position to the center region CA. For example, the height of the protection layer precursor 410 may increase as a distance from the position to the side surfaces of the second semiconductor chips 200 decreases. Alternatively, the height of the protection layer precursor 410 may increase as it moves from the side surface of the first semiconductor chip 100 to the center region CA. The protection layer precursor 410 may be provided to surround (e.g., enclose) the lowermost one of the side surfaces of the second semiconductor chips 200. However, the present disclosure is not limited to this example, and in an embodiment, the protection layer precursor 410 may be provided to at least partially surround (e.g., enclose) the side surfaces of lower ones of the second semiconductor chips 200 adjacent to the first semiconductor chip 100. The protection layer precursor 410 may include an insulating material and may include an epoxy-based polymer precursor.

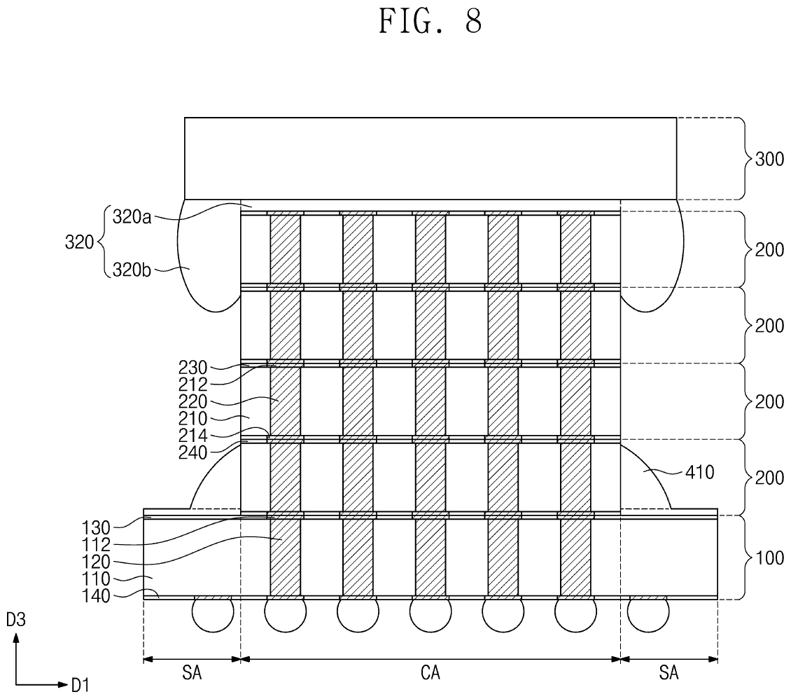

Referring to FIG. 8, the third semiconductor chip 300 may be provided on the second semiconductor chips 200. Here, the third semiconductor chip 300 may be the same as the third semiconductor chip 300 described with reference to FIG. 1. An adhesive material may be provided between the third semiconductor chip 300 and the uppermost one of the second semiconductor chips 200. The adhesive material may be provided to fill a space between the third semiconductor chip 300 and the uppermost one of the second semiconductor chips 200. The adhesive material may be extended from the space between the third semiconductor chip 300 and the uppermost one of the second semiconductor chips 200 to a region on the side surface of the uppermost one of the second semiconductor chips 200. The adhesive material may extend from the bottom surface of the third semiconductor chip 300 along the side surfaces of the second semiconductor chips 200 to at least partially cover the side surfaces of the second semiconductor chips 200. A second thermal treatment process may be performed to apply heat on the adhesive material. The adhesive material may be cured by the second thermal treatment process to form the adhesive layer 320. The third semiconductor chip 300 may be attached to the uppermost one of the second semiconductor chips 200 by the adhesive layer 320.

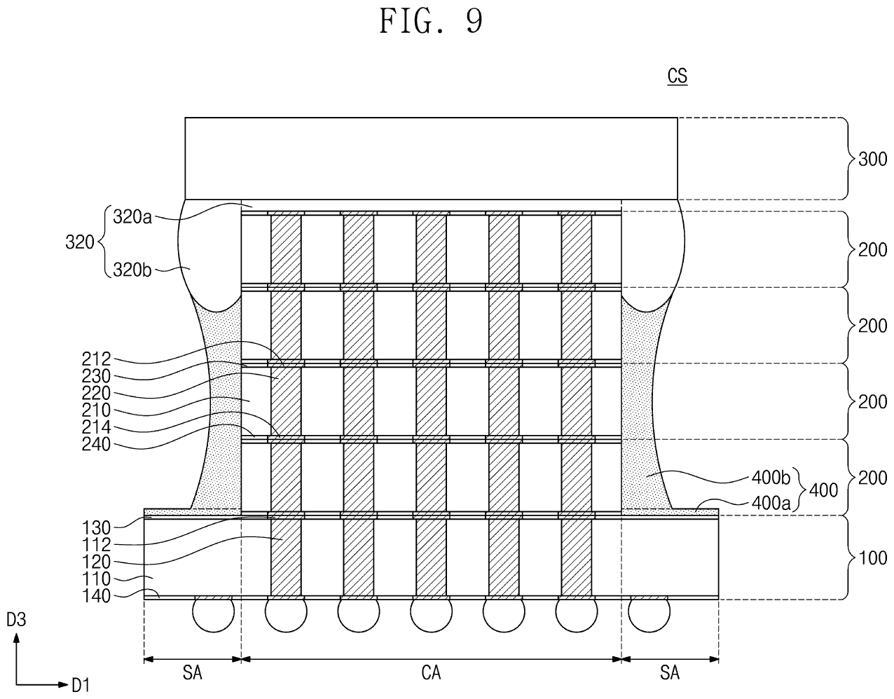

The structure, which is formed by the second thermal treatment process, may have substantially the same features as shown in FIG. 9. Referring to FIG. 9, the protection layer precursor 410 may extend along the side surfaces of the second semiconductor chips 200 by the second thermal treatment process. A top end of the extended protection layer precursor 410 may be in contact with the extension portion 320b of the adhesive layer 320.

According to some embodiments, in the second thermal treatment process of forming the adhesive layer 320 from the adhesive material, a fume, which is produced from the adhesive material, may be formed on the protection layer precursor 410. In detail, the fume may be on the peripheral region SA of the first semiconductor chip 100. Owing to the heat applied in the second thermal treatment process, the fume of the adhesive material may be fused with the protection layer precursor 410. Furthermore, the protection layer precursor 410 may be cured by the heat to form the protection layer 400. That is, the protection layer precursor 410 may be cured, and the fume may be included in the protection layer 400.

In a comparative embodiment, in the case where the protection layer 400 is not formed, the fume of the adhesive material may be formed on the first semiconductor chip 100. The fume may be interposed between the top surface of the first semiconductor chip 100 and a bottom surface of the mold layer 450, and due to the fume, an adhesion strength between the mold layer 450 and the first semiconductor chip 100 may be deteriorated. However, in the semiconductor package according to an embodiment of the present disclosure, the protection layer 400 and the fume may be fused with each other. That is, it may be possible to prevent the adhesion strength between the protection layer 400 and the mold layer 450 from being lowered by the fume. Thus, it may be possible to improve the stability of the semiconductor package.

FIG. 9 illustrates an example, in which the protection layer 400 is formed from the protection layer precursor 410 in contact with the adhesive layer 320 by the second thermal treatment process, but embodiments of the present disclosure are not limited to this example. The adhesive material may be cured by the second thermal treatment process to form the adhesive layer 320. Hereinafter, the protection layer 400 may be formed by additionally performing a third thermal treatment process to cure the protection layer precursor 410. The third thermal treatment process may be performed at the temperature of 120° C. to 200° C., but embodiments of the present disclosure are not limited to this example.

Referring back to FIG. 1, the mold layer 450 may be formed on the first semiconductor chip 100. For example, the mold layer 450 may be formed by coating the top surface of the first semiconductor chip 100 with an insulating material and curing the insulating material. The mold layer 450 may be provided to cover a top surface of the first portion 400a and to surround (e.g., enclose) a side surface of the second portion 400b. The mold layer 450 may be provided to surround (e.g., enclose) a side surface of the adhesive layer 320 and a side surface of the third semiconductor chip 300. The semiconductor package of FIG. 1 may be fabricated through the afore-described process.

In a semiconductor package according to an embodiment of the present disclosure, a protection layer enclosing a chip stack may be formed to prevent a delamination issue from occurring between chips. Thus, a semiconductor package with an improved mechanical property may be provided.

In addition, the protection layer may be formed to have a high adhesion strength to a mold layer, and the delamination between the chip and the mold layer may be prevented. Thus, a semiconductor package with improved stability may be provided.

While non-limiting example embodiments of the present disclosure have been particularly shown and described, it will be understood by one of ordinary skill in the art that variations in form and detail may be made therein without departing from the spirit and scope of the present disclosure.

What is claimed is:

1. A semiconductor package, comprising:
a first semiconductor chip comprising a center region and a peripheral region;
second semiconductor chips stacked on a top surface of the first semiconductor chip, on the center region;
a third semiconductor chip stacked on an uppermost second semiconductor chip from among the second semiconductor chips;
an adhesive layer between the uppermost second semiconductor chip and the third semiconductor chip; and
a protection layer on the top surface of the first semiconductor chip,
wherein the adhesive layer comprises an extension portion that protrudes on a side surface of the uppermost second semiconductor chip, and
wherein the protection layer comprises:
a first portion on the peripheral region, on the top surface of the first semiconductor chip; and
a second portion extending from the first portion to side surfaces of at least two of the second semiconductor chips.

2. The semiconductor package of claim 1, wherein each second semiconductor chip from among the second semiconductor chips comprises:
a lower chip pad at a bottom surface of the second semiconductor chip; and
an upper chip pad at a top surface of the second semiconductor chip, and
wherein the lower chip pad and the upper chip pad of adjacent ones of the second semiconductor chips are in contact with each other.

3. The semiconductor package of claim 1, wherein the adhesive layer comprises a non-conductive film (NCF).

4. The semiconductor package of claim 1, wherein a top end of the second portion of the protection layer is in contact with a bottom end of the extension portion of the adhesive layer.

5. The semiconductor package of claim 1, further comprising a mold layer on the top surface of the first semiconductor chip,
wherein the mold layer is on a top surface of the first portion of the protection layer, and surrounds a side surface of the second portion of the protection layer, a side surface of the extension portion of the adhesive layer, and a side surface of the third semiconductor chip.

6. The semiconductor package of claim 1, wherein the third semiconductor chip further comprises a heat-dissipation pad at a bottom surface of the third semiconductor chip,
wherein the heat-dissipation pad is spaced apart from a top surface of the uppermost second semiconductor chip, and
wherein the adhesive layer surrounds the heat-dissipation pad and is in a space between the uppermost second semiconductor chip and the third semiconductor chip.

7. The semiconductor package of claim 1, wherein a width of the first semiconductor chip is larger than a width of each of the second semiconductor chips, and
wherein a width of the third semiconductor chip is equal to or larger than the width of each of the second semiconductor chips and is smaller than the width of the first semiconductor chip.

8. The semiconductor package of claim 1, further comprising a dam structure on the top surface of the first semiconductor chip, on the peripheral region,
wherein the first portion of the protection layer is between side surfaces of the second semiconductor chips and an inner side surface of the dam structure.

9. The semiconductor package of claim 1, wherein the protection layer comprises an epoxy-based polymer.

10. A semiconductor package, comprising:
a first semiconductor chip comprising a center region and a peripheral region;
second semiconductor chips stacked on a top surface of the first semiconductor chip, on the center region,;
a third semiconductor chip on an uppermost second semiconductor chip from among the second semiconductor chips;
an adhesive layer between the uppermost second semiconductor chip and the third semiconductor chip;
a protection layer on the top surface of the first semiconductor chip, on the peripheral region; and
a mold layer on the top surface of the first semiconductor chip and surrounding the second semiconductor chips and the third semiconductor chip,
wherein the adhesive layer comprises an extension portion that extends along side surfaces of the second semiconductor chips from a bottom surface of the third semiconductor chip,
wherein the protection layer comprises:
a first portion on the top surface of the first semiconductor chip, on the peripheral region; and
a second portion extending from the first portion to the side surfaces of at least two of the second semiconductor chips, and
wherein a width of the protection layer decreases as a distance from a top surface of the second portion and a bottom surface of the second portion increases.

11. The semiconductor package of claim 10, further comprising a dam structure on the top surface of the first semiconductor chip, on the peripheral region,
wherein the first portion of the protection layer is between side surfaces of the second semiconductor chips and an inner side surface of the dam structure.

12. The semiconductor package of claim 10, wherein the first semiconductor chip comprises a first upper chip pad at the top surface of the first semiconductor chip,
wherein each second semiconductor chip from among the second semiconductor chips comprises:
a second lower chip pad at a bottom surface of the second semiconductor chip; and
a second upper chip pad at a top surface of the second semiconductor chip,
wherein the second lower chip pad and the second upper chip pad of adjacent ones of the second semiconductor chips are in contact with each other, and
wherein the second lower chip pad of a lowermost second semiconductor chip among the second semiconductor chips is in contact with the first upper chip pad of the first semiconductor chip.

13. The semiconductor package of claim 12, wherein a top end of the second portion of the protection layer is in contact with a bottom end of the extension portion of the adhesive layer.

14. The semiconductor package of claim 10, wherein the third semiconductor chip comprises heat-dissipation pads at the bottom surface of the third semiconductor chip,
wherein the heat-dissipation pads are spaced apart from a top surface of the uppermost second semiconductor chip, and
wherein the adhesive layer surrounds the heat-dissipation pads and is between the uppermost second semiconductor chip and the third semiconductor chip.

15. The semiconductor package of claim 10, wherein the protection layer comprises an epoxy-based polymer.

16. The semiconductor package of claim 10, wherein a height of the first portion of the protection layer is in a range from 1μm to 10μm.

17. A method of fabricating a semiconductor package, comprising:
vertically stacking second semiconductor chips on a center region of a first semiconductor chip, wherein the second semiconductor chips are directly bonded to each other;
coating a peripheral region of the first semiconductor chip, that surrounds the center region, with a protection layer precursor;
providing a third semiconductor chip on a top surface of an uppermost second semiconductor chip from among the second semiconductor chips, wherein the providing comprises attaching the third semiconductor chip to the top surface of the uppermost second semiconductor chip by an adhesive layer between the top surface of the uppermost second semiconductor chip and the third semiconductor chip; and
forming a protection layer by the protection layer precursor being extended along side surfaces of at least two of the second semiconductor chips, wherein a top end of the protection layer is in contact with the adhesive layer.

18. The method of claim 17, wherein the forming the protection layer comprises:
applying heat to the protection layer precursor and the adhesive layer such that the protection layer precursor extends along the side surfaces of the second semiconductor chips and contacts the adhesive layer; and
curing the protection layer precursor to form the protection layer.

19. The method of claim 17, wherein a width of the third semiconductor chip is equal to or larger than a width of each of the second semiconductor chips,
wherein the adhesive layer includes an extension portion that extends on the side surfaces of the second semiconductor chips, and
wherein the top end of the protection layer is in contact with a bottom end of the extension portion of the adhesive layer.

20. The method of claim 17, further comprising forming a mold layer on the top surface of the first semiconductor chip, wherein the mold layer surrounds the second semiconductor chips and the third semiconductor chip,
wherein the forming the mold layer is performed after the forming the protection layer.
